(19) United States
(12) Patent Application Publication
(10) Pub. No.: US 2003/0062911 A1
(43) Pub. Date: Apr. 3, 2003

(54) Apparatus and method for detecting the AC component of a signal

(76) Inventors: Cheng-Yung Kao, Hsinchu (TW); Wen-Tsao Chen, Hsinchu (TW)

Correspondence Address: LAW OFFICE OF LIAUH & ASSOC., 4224 WAIALAE AVE, STE 5-388, HONOLULU, HI, 96816

(21) Appl. No.: 09/971,420

(22) Filed: Oct. 3, 2001

(51) Int. Cl. G01R 27/08

(52) U.S. Cl. 324/724

(57) ABSTRACT

A method and apparatus for detecting the AC component of a signal. The present invention, which uses with a digital multimeter in a DC mode allows the DC component of a signal to be detected simultaneously with the measurement of the signal without affecting the measurement precision of the signal, is most advantageous for use in situations where the presence of the AC component, and not its precise magnitude, is what needs to be known. This apparatus for detecting the AC component of a signal comprises a filter to obtain DC component of the signal followed by a differential A/D converter, to which the signal and the DC component are fed in order to obtain the AC component that will be processed later by integral/deintegral manipulations, and a timing controller to control the integral time of the integral/deintegral manipulations to prevent the frequency of the AC component of the signal being an integer multiplication of the inverse of the integral time so that the integral/deintegral manipulations fail to detect the AC component of the signal. Finally a display is used to show the AC component of the signal in digital format.

### BACKGROUND OF THE INVENTION

1. Field of Invention

The present invention relates to an apparatus and method for detecting the AC component of a signal, which can be particularly used to measure the signal and detect its AC component when using a digital multimeter in a DC mode at the same time without affecting measurement precision. This invention is most advantageous for use in situations where only the knowledge of the existence of the AC component of a signal is important, but not the precise magnitude of the AC component.

2. Related Art

Nowadays, there is a plurality of apparatus can be used to measure signals. Some of them are designed so complex that they have versatile functions and can measure signals precisely, and some of the others are specially designed to be easily used and only have some simple functions. All the measurement apparatus may function differently according to their design purposes. However, for those simple and economic ones, the measurement functions are usually limited and the precision is also poor.

For example, a digital multimeter is used as a voltmeter, galvanometer and ohmmeter, which measures an AC or DC Voltage, an AC or DC current and resistance. In the digital multimeter, all input signals are transformed into DC voltage which is displayed through the transformation by an A/D converter.

The digital multimeter generally adopts the dual-slope A/D converter scheme for signal measurement, which can transform the signal into time parameter. After a counter recording the time parameter, a number would be displayed by transforming the counting number into the digital output code. The dual-slope A/D converter includes a RC integrator and its function will be described as follows:

Usually, the operation of the dual-slope A/D converter can be divided into two groups in time: (1) AZ(Auto-Zero), INT(Integration), DINT(De-Integration), or (2) AZ(Auto-Zero), INT(Integration), DINT(De-Integration), ZI(Zero-Integration). Wherein during the time interval of ZI, the integral capacitor will be discharged rapidly, and in the AZ time interval, the dual-slope A/D converter will be used not only to discharge the integral capacitor but also store the offset voltage of the RC integrator of the dual-slope A/D converter and the comparator and the buffer of the digital multimeter in order to prevent affecting the measurement of the signal. Finally, the measured values are converted into a format that is recognized by an LCD during the INT and DINT time intervals.

As shown in FIG. 1, it is the illustration of a conventional RC integrator, wherein Rint and Cint are the resistor and capacitor values in the INT time interval, respectively, and Rdint and Cdint are the resistor and capacitor values in the DINT time interval, respectively. The measured Vin, which is the difference of the differential pairs inputs, is fed to the integrator at the beginning of and stop feeding at the ending of the INT time interval for a fixed time duration Tint. Immediately, the DINT time interval starts and a reference voltage Vr will then be fed to the integrator for a fixed time duration Tdint such as to discharge the integral capacitor to the initial state. Consequently, according to the Charge Conservation Theorem:

Vin*Tint/(Rint*Cint)=Vr*Tdint/(Rdint*Cdint)

That is,

Tdint=(Vin/Vr)*(Rdint/Rint)*(Cdint/Cint)*Tint

For example, if Vin=400 mV, Vr=100 mV, Rdint=Rint, Cdint=Cint, Tint=100 ms, therefore, the maximum value of Tdint is calculated as 400 ms according to the above equation. Such value of Tdint is sampled in the frequency of 10 kHz such as to result in 4000 times of sampling by the counter, which is transformed and showed as 400.0 mV on the LCD display. Briefly, if Vin=10 mV and the conditions are the same as above, there is showed as 10.0 mV on the LCD display, and so on.

However, the method described above is used only as a DC mode which can measure the DC component not the AC component of the signal or an AC mode which measures the AC component not the DC component of the signal of the digital multimeter. If the read-out value on the LCD display of the digital multimeter comes into unchanged in the DC mode, it should not be assumed that the signal has only the DC component. As shown in FIG. 2, if the frequency of the AC component of the signal is exactly an integer multiplication of the inverse of the integral time (1/Tint), therefore during the integral time interval, the integration of the positive and negative magnitudes of the AC component of the signal will be cancelled out each other such that it is not possible to ensure the existence of the AC component of the signal.

Therefore, a conventional usage of a digital multimeter for measuring a signal is described as follows. Generally, users should switch the digital multimeter to the DC measurement state for measuring the signal and then switch to the AC measurement state so as to measure the signal and ensure the existence of the AC component.

### SUMMARY OF THE INVENTION

The primary object of the invention is to provide an apparatus and method for measuring a signal in the DC mode of a digital multimeter and detecting its AC component at the same time without affecting measurement precision.

To achieve the object mentioned above, the present invention provides a method for detecting the AC component of a signal for use with a digital multimeter, which comprises the steps as follows: first, extracting the DC component of the signal to be a DC component signal by using a filter. Second, differentially feeding the signal and the DC component signal to an A/D converter to obtain an AC component signal. Third, converting the AC component signal into a digital output code by using the A/D converter. Fourth, providing a timing signal from a timing controller for the A/D converter to adjust the integral time of the A/D converter when the value of the digital output code, which is continuously sampled for a specified times, is always below a reference value. Finally, driving the display to show by using a display driver according the digital output code.

According to the method descrived above, the present invention provides an apparatus for detecting the AC component of a signal, which comprises a filter, an A/D converter, a timing controller, and a display driver. First of all, the filter is used to obtain the DC component of the signal followed by the A/D converter, to which the signal and the DC component are fed by the way of differential input to obtain the AC component of the signal and the corresponding digital output code. Furthermore, according to the value of the digital output code, the timing controller will provide a corresponding timing signal to adjust the integral time of the A/D converter. Finally, the display driver will drive the display to show appropriate values according to the digital output code.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 discloses a circuit diagram of the RC integrator of a conventional dual-slope A/D converter;

FIG. 2 discloses a diagram for showing the integral status of a conventional dual-slope A/D converter when the frequency of the AC component of a signal is exactly an integer multiplication of the inverse of the integral time;

FIG. 3 discloses a block diagram of an embodiment of the apparatus for detecting the AC component of a signal according to the present invention;

FIG. 4 discloses a circuit diagram of an embodiment of the RC integrator of the dual-slope A/D converter according to the present invention; and

FIG. 5 discloses a diagram for showing an embodiment of the display in bargraph format according to the present invention.

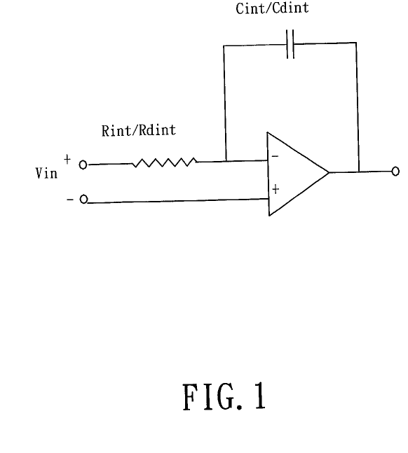

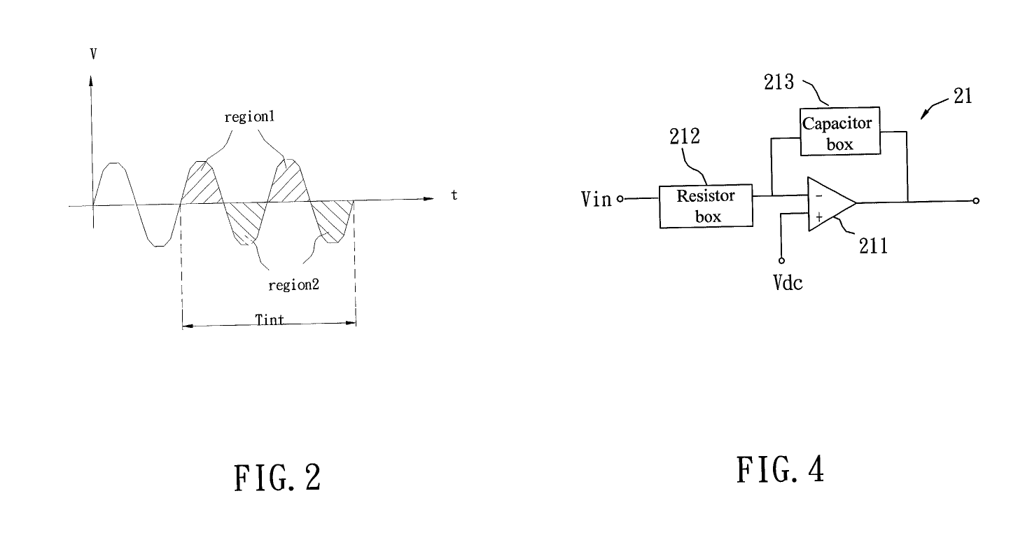

### DETAILED DESCRIPTION OF THE INVENTION

The present invention is based on the usage of the digital multimeter. More specifically, the invention is based on the usage of the dual-slope A/D converter and developing a new function of the digital multimeter, that is, detecting and displaying the AC component of a signal in the DC mode of the digital multimeter.

The principle of the present invention will be illustrated thereinafter. First of all, if input signal Vsignal includes a DC component Vdc and an AC component Vac, that is, Vsignal=Vdc+Vac, it is filtered by a low pass filter and leaves the DC component Vdc. The Vsignal and Vdc are sent to the differential pairs of RC integrator. The difference of the differential pairs is equal to Vac.. The input of the dual-slope A/D converter will be the AC component of the signal Vsignal, that is, Vac, but the input has to be amplified for measuring. There are several methods for amplifying the signal Vac described as follows: (1) changing the frequency of the counter during the DINT time interval (2) changing the reference voltage Vr during the DINT time interval (3) using different resistors which are Rint and Rdint during the INT and DINT time interval.

Second of all, if the counting number is still too small to be measure after the differential signal Vac is amplified, a “digital control system” is used to change the integral time to increase the counting number for preventing the integral time near an integer multiplication of the inverse of the integral time.

Finally, for displaying the AC component of the signal in the DC mode of the digital multimeter, the two dual-slope A/D converters of the digital multimeter have to be used at the same time, which one of the converters is used as a high resolution converter to transfer the displaying of the number part of a display and the other is used as a high speed converter to transfer the displaying of the bargraph of the display. Normally, the number and the bargraph of the display show the amplitude of the signal, and the polarity sign of the bargraph part shows the polarity of the signal. The present invention uses the bargraph part of the display to show the AC component in the DC mode, and it is a new function which the prior digital multimeter does not have.

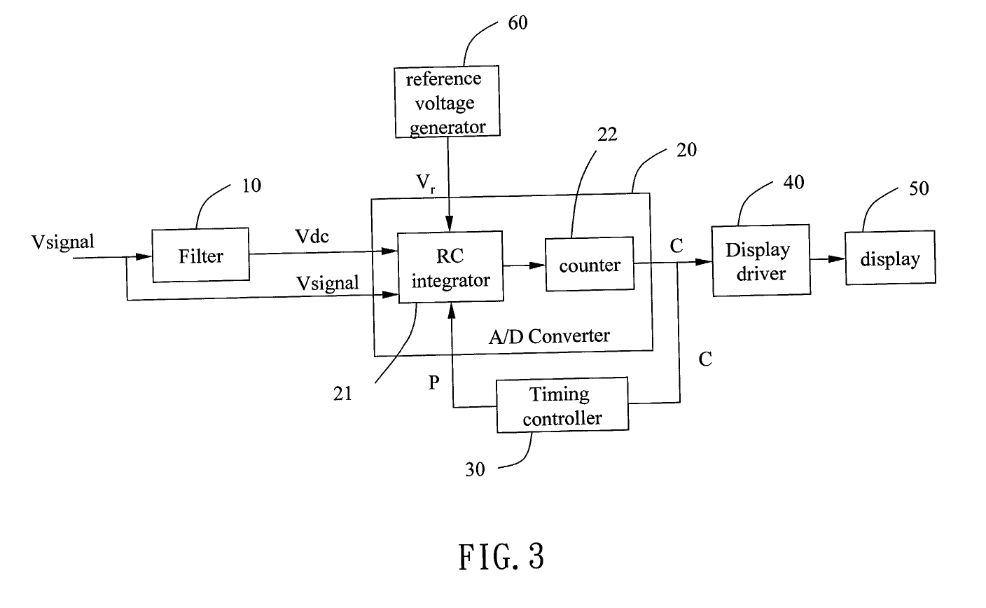

According to the method as above, the present invention provides an apparatus for detecting the AC component of a signal, which is used in the DC mode of a digital multimeter. With reference to FIG. 3, the apparatus for detecting the AC component of the signal according to the present invention primarily comprises: a filter 10, which may be a low-pass filter or an alternative with the same finction and is used for extracting the DC component signal Vdc of the input signal Vsignal; an A/D converter 20, which may be a dual-slope A/D converter or an alternative with the same function and comprises a RC integrator 21 and a counter 22, wherein the input signal Vsignal and the DC component signal Vdc are differentially fed to the A/D converter 20 to obtain an AC component signal Vac that will be integrated/deintegrated later by the RC integrator 21, and the counter 22 is used to count the integral time of the differential manipulation of the RC integrator 21 and convert the result into a corresponding digital output code C; a timing controller 30, which is used to provide a timing signal P to adjust the integral time of the A/D converter 20; and a display driver 40, which is used to drive a display 50 to show according to the digital output code C. Moreover, The apparatus for detecting the AC component of a signal also comprises a reference voltage generator 60, which is used to provide the A/D converter 20 with a reference voltage Vr. In FIG. 3, the present invention adds two parts according to the method described above, which comprises: filter 10 for filtering the AC component of the signal, the timing controller 30 for changing the integral time as the “digital control system” described above and reference voltage generator 60 for changing the reference voltage Vr.

A preferred embodiment of the apparatus for detecting the AC component of a signal according to the present invention is depicted in FIG. 3. First of all, the input signal Vsignal is fed to the filter 10 for obtaining the DC component signal Vdc of the input signal Vsignal. The DC component signal Vdc and the input signal Vsignal are then fed differentially to the RC integrator 21 to obtain the AC component signal Vac of the input signal Vsignal. Furthermore, the timing controller 30 is used to provide the timing signal P to the A/D converter 20 and adjust its integral time. At the meanwhile, the reference voltage generator 60 will also provide the A/D converter 20 with a reference voltage Vr so that the RC integrator 21 can integrate and differentiate the AC component signal Vac according to the timing signal P and the reference voltage Vr. Finally, the counter 22 is used to count the integral time of the differential manipulation of the RC integrator and convert the result into the digital output code C.

Wherein, the structure of the RC integrator 21 is depicted in FIG. 4, which comprises a operational amplifier 211, a resistor box 212, and a capacitor box 213, wherein the resistor and capacitor values of the resistor box 212 and the capacitor box 213 is changed into several different values. And by changing the resistor and capacitor values of the resistor box 212 and the capacitor box 213, the integral time of the deintegration manipulation of the RC integrator 21 is adjusted so as to amplify the magnitude of the AC component signal Vac and control the value of the digital output code C obtained from the counter 22 within a desired range.

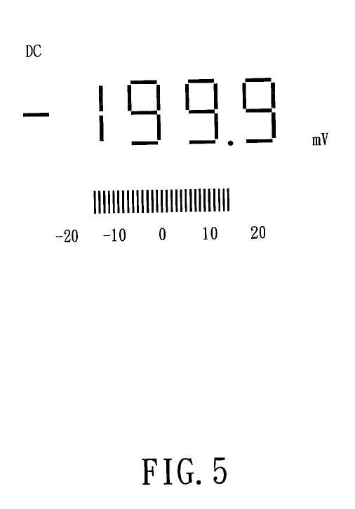

Furthermore, the timing controller 30 will periodically check the value of the digital output code C at specific time intervals to verify whether it is below a reference value, this is to ensure that, the frequency of the AC component signal Vac of the input signal Vsignal may be exactly or nearly an integer multiplication of the inverse of the integral time (1/Tint), and provide the corresponding timing signal P to the A/D converter 20 to adjust the integral time of the RC integrator 21. At the meanwhile, the digital output code C is feed to the display driver 40 so as to be shown on the display 50 in the LCD numerical figures or in the bargraph format. Wherein, the preferred embodiment for showing in the bargraph format is depicted in FIG. 5, where the measured value of the input signal Vsignal is shown by numerical figures and the bargraph on the bottom of the figure is used to show the existence of the AC component signal of the input signal Vsignal. If the polarization of the AC component signal is positive, the bargraph will be lighted up from center to right, and if the polarization of the AC component signal is negative, the bargraph will be lighted up from center to left. This specific example in FIG. 5 indicates that the polarization of the AC component is positive.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An AC component of a signal detecting method for use with a digital multimeter in a DC mode, which is used to detect the existence of the AC component of the signal and to show the result on a display, comprising the steps of:
extracting the DC component of the signal to be a DC component signal by using a filter;
differentially feeding the signal and the DC component signal to an A/D converter to obtain an AC component signal;
converting the AC component signal into a digital output code by using the A/D converter;
providing a timing signal from a timing controller for the A/D converter to adjust the integral time of the A/D converter when the value of the digital output code, which is continuously sampled for a specified times, is always below a reference value; and
driving the display to show by using a display driver according the digital output code.

2. The method of claim 1, wherein the method also comprises:
providing a reference voltage from a reference voltage generator for the A/D converter.

3. The method of claim 1, wherein the display is a LCD display.

4. The method of claim 1, wherein the AC component of a signal shows in a bargraph format on the display.

5. The method of claim 4, wherein the method also comprises:
lighting up the bargraph from center to right if the polarization of the AC component signal is positive; and
lighting up the bargraph from center to left if the polarization of the AC component signal is negative.

6. The method of claim 1, wherein the filter is a low-pass filter.

7. The method of claim 1, wherein the A/D converter is a dual-slope a A/D converter.

8. The method of claim 1, wherein the method for amplifying the AC component signal and converting into a digital output code comprises:
integrating/deintegrating the AC component signal by using a RC integrator;
adjusting the integral time of integral/deintegral manipulations of the RC integrator for the AC component signal according to the timing signal; and
counting the integral time of the differential manipulation of the RC integrator by using a counter and converting the result into the digital output code.

9. The method of claim 8, wherein the RC integrator comprises an operational amplifier, at least one resistor, and at least one capacitor.

10. The method of claim 9, wherein the values of the resistor and the capacitor can be adjusted in order to amplify the AC component signal.

11. An AC component of a signal detecting apparatus for use with a digital multimeter in a DC mode, which is used to detect the AC component of the signal and to show the result on a display, comprising:
a filter for extracting the DC component of the signal to be a DC component signal;
an A/D converter, to which the signal and the DC component signal are differentially fed in order to obtain an AC component signal that is then converted into a corresponding digital output code;
a timing controller for providing a timing signal to the A/D converter to adjust the integral time of the A/D converter; and
a display driver for driving the display to show according to the digital output code.

12. The apparatus for detecting the AC component of a signal of claim 11 wherein the apparatus also comprises:
a reference voltage generator for providing the A/D converter with a reference voltage.

13. The apparatus for detecting the AC component of a signal of claim 11 wherein the display is a LCD display.

14. The apparatus for detecting the AC component of a signal of claim 11 wherein the AC component of a signal shows in a bargraph format on the display.

15. The apparatus for detecting the AC component of a signal of claim 11 wherein the filter is a low-pass filter.

16. The apparatus for detecting the AC component of a signal of claim 11 wherein the A/D converter is a dual-slope A/D converter.

17. The apparatus for detecting the AC component of a signal of claim 16 wherein the dual-slope A/ID converter comprises:
a RC integrator, to which the signal and the DC component signal are fed in order to obtain the AC component signal, and the integral time of integral/deintegral manipulations for the AC component signal can be adjusted according to the timing signal; and
a counter for counting the integral time of the differential manipulation of the RC integrator and converting the result into the digital output code.

18. The apparatus for detecting the AC component of a signal of claim 17 wherein the RC integrator comprises an operational amplifier, at least one resistor, and at least one capacitor.

19. The apparatus for detecting the AC component of a signal of claim 18 wherein the values of the resistor and the capacitor can be adjusted in order to amplify the AC component signal.
